(19) United States
(12) Patent Application Publication
(10) Pub. No.: US 2025/0210080 A1
(43) Pub. Date: Jun. 26, 2025

(54) MAGNONIC COMBINATORIAL MEMORY

(71) Applicant: The Regents of the University of California, Oakland, CA (US)

(72) Inventor: Aleksandr Khitun, Long Beach, CA (US)

(21) Appl. No.: 18/987,245

(22) Filed: Dec. 19, 2024

Related U.S. Application Data
(60) Provisional application No. 63/613,583, filed on Dec. 21, 2023.

(51) Int. Cl. G11C 7/22; G11C 7/10; H03L 7/081

(52) U.S. Cl. CPC G11C 7/222; G11C 7/1006; H03L 7/0814

(57) ABSTRACT

A data storage apparatus includes N memory cells, where N is an integer greater than 1. Each memory cell is controllable to conform to a plurality of path arrangements. The data storage apparatus is configured to store data using a collective path arrangement of the N memory cells. One example implementation uses spin wave propagation routes to store the data.

### CROSS-REFERENCE TO RELATED APPLICATIONS

This patent document claims the benefit of priority of U.S. Provisional Patent Application 63/613,583, filed on Dec. 21, 2023, entitled “Magonic Combinatorial Memory.” All contents of the aforementioned patent application are incorporated by reference herein in entirety.

### STATEMENT REGARDING FEDERALLY SPONSORED RESEARCH

This invention was made with government support under Grant No. 2006290 awarded by National Science Foundation (NSF). The government has certain rights in the invention.

### TECHNICAL FIELD

The present document generally relates to data storage device, and particularly, magnetic memory storage devices.

### BACKGROUND

Many electronic device include, or rely on, storage of data in the form of binary data. The amount of data stored in electronic device has steadily reason over many years. At the same time, the amount of space used and power consumed to read, write, or store such data has steadily decreased over time.

### BRIEF SUMMARY

In various embodiments disclosed in the present document, techniques for data storage using combinatorics are described.

In one example aspect, a data storage apparatus is disclosed. The apparatus includes N memory cells, where N is an integer greater than 1; wherein each memory cell is controllable to conform to a plurality of arrangements, and wherein the data storage apparatus is configured to store data using a collective arrangement of the N memory cells. For example the plurality of arrangements may be plurality of path arrangements and the data is stored using the collective arrangement of paths among the N memory cells.

In another example aspect, a method of storing information is disclosed. The method includes configuring N memory cells, where N is an integer greater than 1. Each memory cell is controllable to conform to a plurality of arrangements, and the data storage apparatus is configured to store data using a collective arrangement of the N memory cells; and storing the information into the N memory cells. In some embodiments, the plurality of arrangements refer to path arrangements among the N memory cells, and preferably among cells on opposite edges of a matrix formed by the arrangement of the memory cells in a 2D manner.

These, and other, aspects are described throughout the present document.

### BRIEF DESCRIPTION OF THE DRAWINGS

FIGS. 1A and 1B depict example schematics of a random access memory (RAM) organization.

FIGS. 2A to 2C depicts an example of a grid of cells.

FIGS. 2D to 2G further illustrate how information may be coded into paths.

FIGS. 3A to 3D depict examples of multi-path active ring circuits.

FIG. 4 shows an example schematic of a magnonic combinatorial memory (MCM).

FIG. 5 shows an example circuit for an MCM.

FIG. 6A-6B depict arrangement of power sensors in a circuit model.

FIGS. 6C to 6K disclose an illustrative example of operation of a 3×3 (9 memory cell) configuration.

FIGS. 7A-7C present details of an example prototype.

FIG. 7D shows four graphs presenting some of the experimental results showing spin wave transmission through film of a prototype.

FIG. 8 shows an example schematics of a circuit with magnet configuration and the output power distribution.

FIG. 9 shows an example schematics of another circuit with magnet configuration and the output power distribution.

FIG. 10 depicts an example of experimental data obtained for different magnet combinations and four selected phases.

FIG. 11 depicts an example of a memory storage apparatus.

FIG. 12 depicts an example of a method of storing information to a memory storage apparatus.

FIG. 13 presents table I (truth table example of a magnonic combinatorial memory MCM).

FIG. 14 presents table II capturing results of experimental data from different magnet configurations.

FIG. 15 shows an example configuration of memory cells in which prime-number based partitioning of memory cells is used to achieve uniqueness of phase shifts for paths.

### DETAILED DESCRIPTION

The present documents several techniques for data storage. The storage density (e.g., the number of bits stored per area/volume) exceeds all the existing prototypes.

### 1. Brief Overview

This patent document discloses, among other technologies, a type of magnetic memory where information is encoded into the mutual arrangement of magnets. Some embodiments may incorporate one or more of the following features. The device may be an active ring circuit comprising magnetic and electric parts connected in series. The electric part includes a broad-band amplifier, phase shifters, and attenuators. The magnetic part is a mesh of magnonic waveguides with magnets placed on the waveguide junctions. There are amplitude and phase conditions for auto-oscillations to occur in the active ring circuit. The frequency(s) of the auto-oscillation and spin wave propagation path(s) in the magnetic part depends on the mutual arrangement of magnets in the mesh. The propagation path is detected with a set of power sensors. The correlation between circuit parameters and spin wave path is the basis of memory operation. The combination of input/output switches connecting electric and magnetic parts, and electric phase shifters constitute the memory address. The output of the power sensors is the memory state. We present experimental data on the proof-of-the-concept experiments on the prototype with three magnets placed on top of a single-crystal yttrium iron garnet Y₃Fe₂(FeO₄)₃ (YIG) film. There are three selected places for the magnets to be placed. There is a variety of spin wave propagation paths for each configuration of magnets. The results demonstrate a robust operation with an On/Off ratio for path detection exceeding 35 dB at room temperature. The number of possible magnet arrangements scales factorially with the size of the magnetic part. The number of possible paths per one configuration scales factorial as well. It makes it possible to drastically increase the data storage density compared to conventional memory devices. Magnonic combinatorial memory with an array of 100×100 magnets can store all information generated by humankind. Physical limits and constraints are also discussed.

### 2. Introduction to Data Storage Capacity Challenges

Information and communication technologies generate vast amounts of data that will far eclipse today's data flow. The global data will grow to 175 zettabytes (ZB) by 2025 according to the International Data Corporation. Conventional storage systems may become unsustainable due to their limited data capacity, infrastructure cost, and power consumption. For example, flash-memory manufacturers would need ˜10⁹ kg of silicon wafers even though the total projected wafer supply is ˜10⁷-10⁸ kg. There is an urgent need for increasing the data storage density (i.e., the number of bits stored per area). In the traditional process of improving the data storage density, better performance is achieved by the miniaturization of the data-storage elements. It stimulates a quest for nanometer-size memory elements such as DNA-based or sequence-defined macromolecules. At the same time, memory architecture and the principles of data storage remain mainly unchanged for the last 50 years.

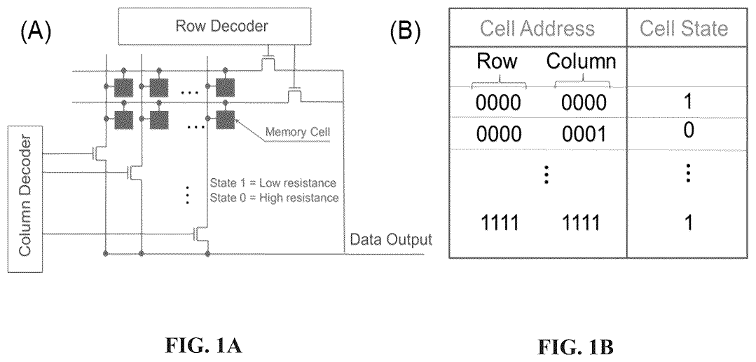

As an example, we would like to refer to Random Access Memory (RAM). FIG. 1A shows example schematics of RAM organization. There is a 2D mesh of memory cells arranged in rows and columns. The addressing of a required cell is accomplished by the row/column decoders. The memory cells may store logical states such as binary 1 and 0 states using low/high resistance. FIG. 1B shows an example of RAM truth table. The first column in the table depicts the memory cell binary address. The second column in the table depicts the cell state. The maximum number of bits stored is limited by the number of memory cells.

In FIG. 1A, there is shown a high-level picture of RAM organization. The core of the structure is an array of memory cells where each cell stores one bit of information. There is a variety of memory cells exploiting different physical phenomena/devices/circuits for data storage such as static RAM, dynamic RAM, magnetic RAM, etc. In all cases, RAM contains multiplexing and demultiplexing circuitry for cell addressing. Typically, the addressing of a required cell is accomplished by transistors electrically connecting the cell on the selected row/column with the output circuit. The correlation between the cell address and cell state is the essence of data storage in RAM. It is illustrated in FIG. 1B in a table, where the first column depicts the memory cell binary address. The second column in the table depicts the cell state (i.e., 0 or 1). Regardless of the physical mechanism of data storage (e.g., mechanical, electrical, magnetic), conventional memory devices make use of the individual states of memory cells. This is the common property of all existing RAMs. The maximum number of bits stored in conventional memory is linearly proportional to the number of memory cells. It is important to note that only one-row and one-column transistors are used for cell addressing. Other combinations (e.g., two rows and two columns, two rows and three columns, etc.) are not used as it does not provide any additional information. For instance, connecting multiple rows with a single column will result in logic state 1 if there is just one cell in the low resistance state. In other words, conventional memory does not use all possible addresses but only a fraction of it. This provides an intriguing possibility of increasing the data storage density by exploiting the collective states of memory cells along with a larger number of possible addresses.

The techniques described in the present document overcomes the above-discussed technical limitation with current data storage technologies, among others. Here, we consider the possibility of building a fundamentally different data-storage device, where information is stored in the collective arrangement of memory cells. It allows embodiments to drastically increase the number of memory states compared to conventional memories. The technical disclosure is organized with section headings to facilitate reading and not to limit scope of disclosed techniques to specific sections or embodiments. In the next Section (Results), we describe the principle of operation of Magnonic Combinatorial Memory (MCM), present the results of numerical modeling illustrating MCM operation, and present experimental data obtained for the prototype. Then, we discuss the results and conclude on the potential advantages and shortcomings of MCM.

### 3. Example Results

### 3.1 Principle of Operation

To explain some features of the combinatorial approach, we refer to the well-known combinatorial problem of counting paths in the grid. There are many possible ways to choose a path from one cell to another cell on a grid. It depends on the grid dimensions and the allowed steps of motion.

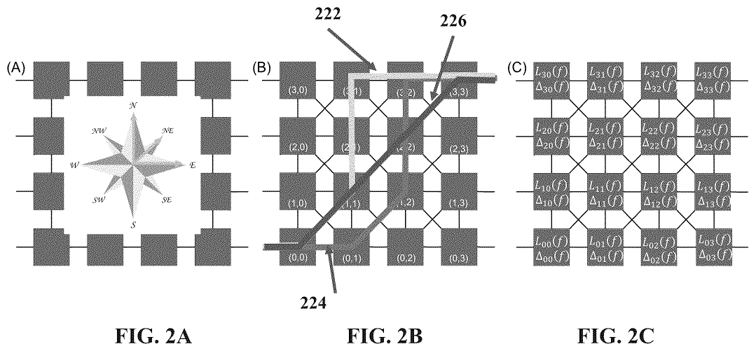

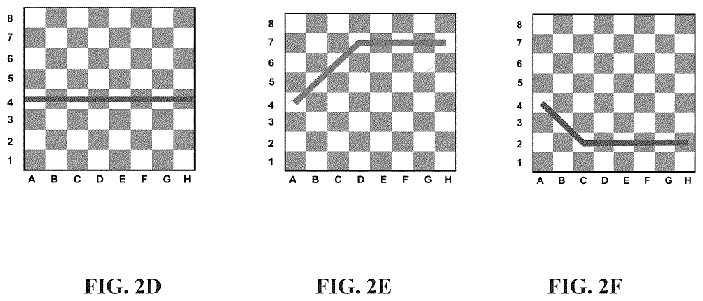

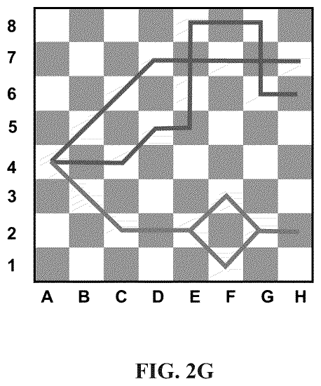

FIG. 2A shows a compass rose to display the orientation of the cardinal directions on the grid, as a reference. In some embodiments, only steps in north, northeast, or east directions are allowed. FIG. 2B shows a schematics of a 4×4 grid. The three curves 222, 224, 226 depict the three possible paths from the southwest corner (0, 0) to the northeast corner (3, 3). FIG. 2C shows schematics of the modified grid where each cell introduces a frequency-dependent attenuation and a phase shift to the propagating wave.

In FIG. 2A, there is shown a 2D mesh of cells and a compass rose. The cells are connected to each other via vertical, horizontal, and diagonal lines. In FIG. 2B, the two numbers in each cell show the cell's coordinates. For instance, the cell in the southwest corner has coordinates (0,0), and the cell in the northwest corner has coordinates (3,3). In FIG. 2B, three possible paths from cell (0,0) to cell (3,3) are shown as 222, 224, 226. These are just three possible paths out of many possible. The total number of paths from the southwest corner (0, 0) of a rectangular grid to the northeast corner (m, n), using only single steps north, northeast, or east is given by Delannoy numbers:

$$D ( m , n ) = {Σ}_{k = 0}^{min ( m , n )} ( \begin{matrix}m \\ k\end{matrix} ) ( \begin{matrix}n \\ k\end{matrix} ) \qquad ( 1 )$$

where k is an integer, the binominal coefficients on the right side of the formula can be compactly expressed using factorial notation as follows:

$$( \begin{matrix}m \\ k\end{matrix} ) = ( \frac{m !}{k ! ( m - k ) !} ) , ( \begin{matrix}n \\ k\end{matrix} ) = ( \frac{n !}{k ! ( n - k ) !} ) \qquad ( 2 )$$

For instance, there are 63 paths connecting cells (0,0) and (3,3) in FIG. 2B. There are hundreds of unique paths as well as path combinations connecting cells on the left side to the cells on the right side of the grid. Some embodiments disclosed herein exploit the huge number of paths in the grid for data storage. Each path can be expressed as a binary number. For example, the path 226 from (0,0) to (3,3) can be expressed as (1000 0100 0010 0001). A binary number corresponding to the path can be considered as a memory state. In contrast to 0 and 1 in conventional RAM, the output of combinatorial memory is a multi-digit binary number corresponding to one of the possible paths.

FIGS. 2D to 2G further illustrate how information may be coded into paths. Starting from the memory cell A4, there may be a number of different paths possible to traverse to the opposite side of the memory cell matrix. FIGS. 2D, 2E and 2F show three examples of such paths. FIG. 2G shows an example highlighting that a number of paths are possible, with many paths possible from same cell on the left to a same cell on the right (e.g., two paths shown between cells A4 and H2). In general, for an 8×8 arrangement as depicted in FIG. 2G, if one path is traversed every one nanosecond, the total amount of time taken to traverse all paths from left to right will be about 13.7 billion years, a number that is greater than the age of the universe.

In order to make use of the multiple paths for data storage, one needs to introduce a correlation between the memory addresses and memory states (for example, make a physical system where a signal propagation path depends on the input conditions). In FIG. 2C, there is shown a modified 2D 4×4 grid, where each cell introduces a frequency-dependent attenuation Lᵢⱼ(f) [dB] and a frequency-dependent phase shift Δᵢⱼ(f) [π] to the propagating signal (e.g., when the signal is a continuous sinusoidal wave). The subscripts denote the cell position in the grid. In this case, waves propagating through the different paths may accumulate different phase shifts and attenuation:

$${L}_{path} ( f ) = {\sum }_{ij} {L}_{ij} ( f ) , {Δ}_{path} ( f ) = {\sum }_{ij} {Δ}_{ij} ( f ) , \qquad ( 3 )$$

where the summation is over all cells in the path. The total phase shift/attenuation for each path depends on the mutual arrangement of memory elements in the mesh. It is possible to have unique phase shifts/attenuation for different paths or to have some paths with the same phase shift/attenuation.

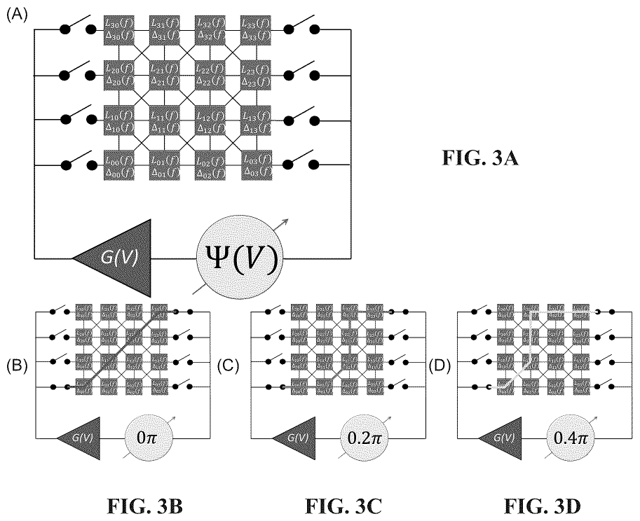

To retrieve information encoded in one or another path in the grid, we propose to utilize an active ring circuit whose schematics are shown in FIG. 3A. It consists of active and passive parts. The active part includes a voltage-tunable broadband amplifier and a voltage-tunable phase shifter. The circuit is configured to amplify signals propagating on resonant paths in the memory cell matrix. The passive part is a 2D grid as shown in FIG. 2C. The parts are connected in series via the sets of switches on the left and right sides of the passive part. There are two conditions for auto-oscillations to occur in the circuit:

$$G ( V ) + L ( f ) \geq 1 , \qquad ( 4.1 )$$

$$Ψ ( V ) + Δ ( f ) = 2 π k , where k = 1 , 2 , 3 , … \qquad ( 4.2 )$$

where G(V) is the gain provided by the voltage-tunable amplifier, L(f) is the signal attenuation in the grid, Δ(f) is the phase shift of the grid, and Ψ(V) is the voltage-tunable phase shift of the electric part. The first equation (4.1) states the amplitude condition for auto-oscillations: the gain provided by the broadband amplifier should be sufficient to compensate for losses in the grid. The second equation states the phase condition for auto-oscillations: the total phase shift for a signal circulating through the ring circuit should be a multiple of 2π. In this case, signals come in phase every propagation round. It is advantageous that the grid parameters are frequency-dependent. The system starts with a superposition of all possible frequencies propagating through all possible paths. Only signals propagating on the resonant frequency(s)/resonant path(s) in the grid are amplified in the active ring circuit. It takes just a few rounds of signal circulation in the ring circuit till the amplitude of the signal propagating through the resonant path goes to the maximum (e.g., saturation).

FIG. 3A-3D is an example schematics of a multi-path active ring circuit. The active part includes a voltage-tunable broadband amplifier G(V) and a voltage-tunable phase shifter Ψ(V). The passive part is the grid as shown in FIG. 2C. Auto-oscillation occurs in the circuit when the active and passive paths are matched in amplitude and phase. (B-D) Illustration of the signal re-routing depending on the position of the voltage-tunable phase shifter. There are three paths shown for the three different positions of Ψ(V): 0π, 0.2π, and 0.4π, respectively. The examples are shown only for one combination of the left/right switches.

Thus, signal propagation paths depend on the position of the phase shifter as illustrated in FIGS. 3B, 3C and 3D. Said differently, the signal propagation paths depend on (i) input/output combination of switches and (ii) the outer phase shifters.

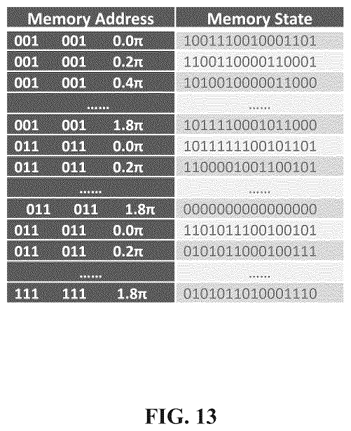

Resonant propagation path(s) depends not only on the position of the phase shifter but also on the combination of left/right switches and the level of amplification G(V). The number of resonant paths increases for higher amplification as condition (4.1) is satisfied for a larger number of frequencies. The correlation between the combination of switches and external phase on one side, and the propagation path on the other side is the base for combinatorial memory operation. Referring to FIG. 13, in Table I, there is shown an example of the truth table of combinatorial memory. The memory address is a multi-digit binary number that is related to the states of the switches and the position of the phase shifter. The memory state is a multi-digit binary number corresponding to the signal propagation path. In contrast to conventional RAMs using only a fraction of possible addresses, the proposed combinatorial memory exploits all the possible combinations of side switches (e.g., two switches in the On state on the left side and three switches in the On state on the right side). It does provide additional information as the grid impedance does depend on the connection configuration. The set of resonant paths with input ports #1 and #2 connected in parallel is not the sum of paths for port #1 and port #2 connected separately. The use of phase in addition to amplitude makes it possible to exploit a larger number of addresses compared to conventional memory.

In general, combinatorial memory can be implemented using different types of waves (e.g., acoustic, electric, optical). Here, we consider a magnonic combinatorial memory combining an active electric part and a passive multi-path magnonic part. There are several reasons for using spin waves. (i) Spin waves interact with magnets which allows us to build a non-volatile memory (for example, no energy is needed to keep magnets in a certain magnetization state). (ii) Spin waves propagate much slower compared to electromagnetic waves which allows us to achieve prominent phase shifts to the propagating signals. (iii) Magnet+magnonic waveguide acts as an efficient frequency filter for spin waves that allows us to exploit micro-magnets as phase shifters and frequency filters at the same time.

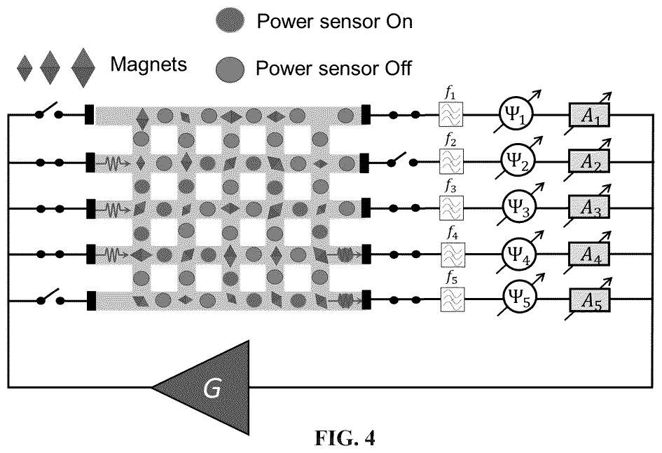

The schematics of an example MCM are shown in FIG. 4. It is an active ring circuit where the passive part consists of a 5×5 mesh of magnonic waveguides shown in the light shaded grid. These waveguides are made of material with low spin wave dumping (e.g., yttrium iron garnet Y₃Fe₂(FeO₄)₃ (YIG)). There are magnets depicted by dual-shaded rhombs placed on top of waveguide junctions. The magnets can be of different sizes and have several thermally stable states of magnetization. These magnets are aimed to act as the frequency filters and phase shifters for the propagating spin waves. Both the direction and the strength of the local magnetic field provided by the magnets are important for spin wave transport. In the ideal scenario, all 25 magnets in the mesh provide different phase shifts and attenuation to the propagating spin waves. There are power sensors placed on top of the waveguides between the junctions. These sensors are aimed to detect the power of the spin wave signal and show the spin wave propagation paths. For example, it may be Inverse Spin Hall Effect (ISHE)-based sensors. Being of a relatively simple material structure (e.g., Pt wire on top of YIG waveguide), ISHE provides an output voltage proportional to the amplitude of the spin wave. There are (2n−1)×n sensors in the mesh (i.e., there are 45 sensors shown in FIG. 4). Each sensor provides a voltage output Vᵢⱼ, where subscripts i and j correspond to the row and column numbers, respectively. The magnonic mesh is connected to the electric part via the input and output ports located on the left and right sides of the mesh. The conversion from electromagnetic wave to spin wave and vice versa may be accomplished by micro antennas. There is a switch (e.g., a transistor similar to one used in conventional memory for row/column addressing) at each input and output port to enable/disable the antenna for signal generation/receiving. These switches are aimed to control the combination of input/output antennas (e.g., input ports #2 and #3, output ports #1, #2, and #5). There are voltage-tunable frequency filters fᵢ, voltage-tunable phase shifters Ψᵢ, and voltage-tunable attenuators Aᵢ at each output port, where the subscript i depicts the output number. The voltage-tunable frequency filters are aimed to maximize the difference in the power on the different output ports. The phase shifters have discrete states corresponding to the specific phase shifts (e.g., Ψ(0)=0π, Ψ(1)=0.25π, Ψ(2)=0.5π, etc.). The tunable attenuators are needed to tolerate possible structure imperfections and equalize the output spin wave power for all ports. There is one broadband amplifier G in the electric part.

Information in MCM is stored in the mutual arrangement of magnets in the mesh. There are n! ways to have an ordered arrangement of n distinct objects. Considering a set of n² distinct magnets in the mesh with n² junctions, the number of ordered arrangements (permutations) is given by

$$\# ordered magnet arrangements = ( {n}^{2} ) ! \qquad ( 5 )$$

In turn, there are a number of spin wave propagation paths for each of the magnet configurations. The total number of paths can be calculated using Eq. (1). The number of paths in a real mesh may even exceed the Delannoy number as there is no restriction to spin waves to propagate in all possible directions (e.g., southwest, northeast, southeast). The number of paths just between the most distant cells scales as follows:

$$\#number of paths ( one input - one output ) \approx ( n + n ) ! / ( n ! \times n ! ) . \qquad ( 6 )$$

The total number of paths from the left side (input) to the right side (output) of the mesh can be found by the summation of paths for all possible combinations of the input and output ports. There is an address assigned to each path. It includes a binary number corresponding to the states of the input switches, a binary number corresponding to the states of the output switches, and a binary number corresponding to the states of the phase shifters Ψᵢ. The binary number for switches is an n-bit number, where 1 corresponds to the state On and 0 corresponds to the state Off. For example, the mesh shown in FIG. 4 has input ports #2, #3, and #4 in the position On. It corresponds to the binary address 01110. The output switches #1, #3, #4, and #5 are in the position On. It corresponds to the binary number 10111. The number of possible combinations of input switches is 2ⁿ−1. It excludes one combination where all input ports are disconnected from the mesh. There is the same number of possible combinations of the output ports. There are more than two states for each phase shifter. In this case, the length of the binary number corresponding to the phase shifter states is related to zⁿ possible combinations, where z is the number of states per phase shifter. The total number of addresses is given as follows:

$$\# adresses = {( {2}^{n} - 1 )}^{2} \times {z}^{n} . \qquad ( 7 )$$

The memory state is the signal propagation path. It is recognized by the set of output voltages Vᵢⱼ provided by the spin wave sensors. One may introduce a reference voltage V_{ref} to digitize the output. For instance, the output state is 1 if Vᵢⱼ≥V_{ref}, and 0 otherwise. Each path is described by (2n−1)×n bits. In the example shown in FIG. 4, the memory state is a sequence of 45 bits (one bit for each sensor). The total capacity of MCM is the product of the number of memory addresses and the number of bits stored per address that can be calculated as follows:

$$\# bits store = {( {2}^{n} - 1 )}^{2} \times {z}^{n} \times n \times ( 2 n - 1 ) \qquad ( 8 )$$

According to Eq.(7), the data storage capacity of MCM scales according to the power law with the size of the mesh. The data storage capacity of conventional memory scales linearly with the number of memory elements n×n. It is important to note, that the number of possible magnet arrangements given by Eq.(5) scales faster than the number of bits that can be addressed in Eq.(7). It may be possible to find an arrangement of magnets (i.e., one of many possible) that provides the desired spin wave propagation paths (i.e., information stored). The maximum number of unique phase addresses zⁿ in Eq.(7) is limited by the number of paths given by Eq.(6). It may be not practically feasible to utilize a number of phase states. Nevertheless, the number of information stored in MCM is skyrocketing even for a small number of phase states. For example, assuming z=4 (i.e., four phases per phase shifter), MCM with 25 magnets (n=5), as shown in FIG. 4, can store up to 10 Mb of data. MCM with 100 magnets (n=10) can store up to 1 TB of data. MCM with a 100×100 (n=100) magnet array can store all the information generated by humankind.

### 3.2 Results of Numerical Modeling

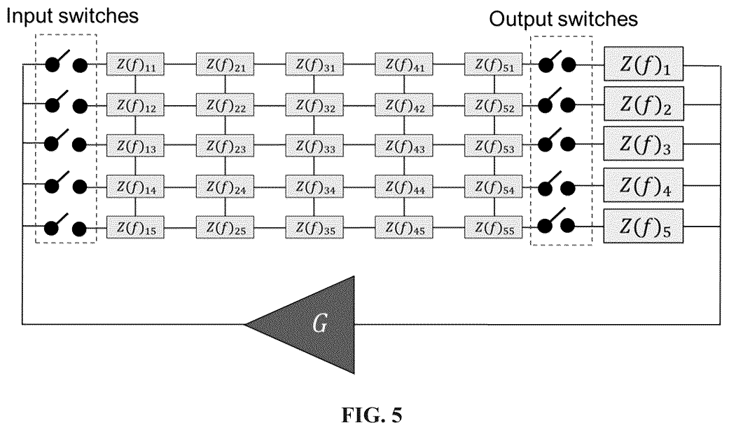

The spin wave propagation path depends on the mutual arrangement of magnets in the magnonic mesh. This is one advantageous feature of MCM operation. In order to illustrate it, we present the results of numerical modeling. In FIG. 5, there is shown an equivalent circuit for an example MCM. The mesh of waveguides with magnets is replaced with a 2D mesh of impedances. The real and the imaginary part of each cell corresponds to the spin wave attenuation and phase shift accumulated during propagation through the junction. Rigorously speaking, there should be additional cells in the mesh (i.e., impedances) to account for spin wave damping and accumulated phase shift during the propagation between the junctions. To simplify our consideration, we assume that the damping and the phase shift during the propagation between the junctions are much smaller compared to the ones during the propagation through the junction. The real and the imaginary parts of the junction impedances are frequency-dependent. Their values may be obtained from micromagnetic simulations or from experiments. Thus, FIG. 5 shows an equivalent circuit for MCM. The mesh of waveguides with magnets is replaced with a mesh of cells with impedances Z(f)ᵢⱼ, where subscripts i and j correspond to the column and row numbers, respectively. The real and the imaginary part of each cell are frequency-dependent and correspond to the spin wave attenuation and phase shift accumulated while propagating through the junction. The output bandpass filters, phase shifters, and attenuators are replaced by the frequency depend on impedances Z(f)ⱼ, where subscript j corresponds to the row number.

There are three steps in the modeling procedure. First, one needs to find the total attenuation and the phase shift produced by the passive part for all possible frequencies. Second, the obtained results are checked to find the frequency(s) at which the self-oscillation conditions (4.1) and (4.2) are met. Finally, one needs to find the map of spin wave power flow through the mesh at the resonant frequency(s). The most time-consuming is the first step as it takes a number of subsequent calculations to find the mesh responses in a wide frequency range. In order to speed up calculations and illuminate the essence of the proposed memory, we make several assumptions. (i) We assume that each propagation path in the mesh is associated with a certain propagation frequency. (ii) The attenuation is linearly proportional to the propagation distance. (iii) The junctions provide a frequency-independent phase shift. The objective is to show the change in the signal propagation paths depending on the arrangement of a given set of elements in the mesh.

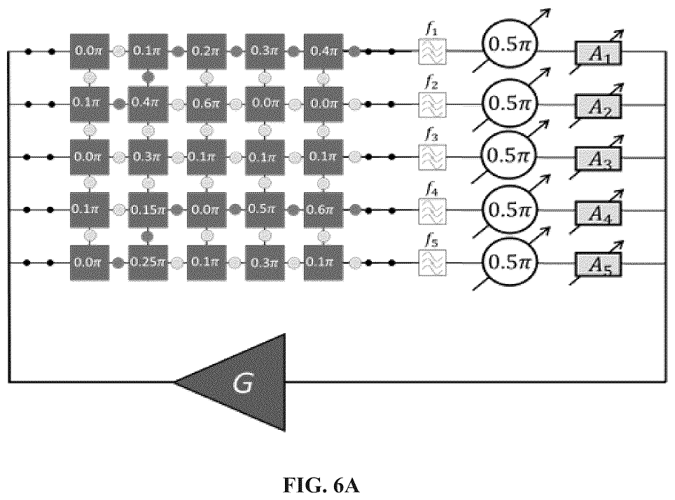

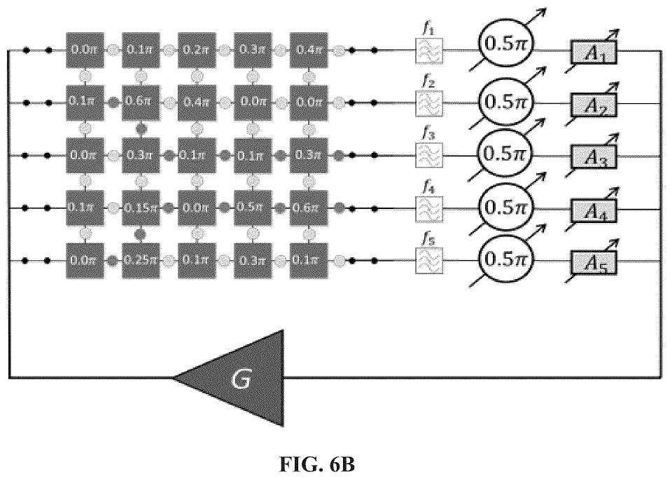

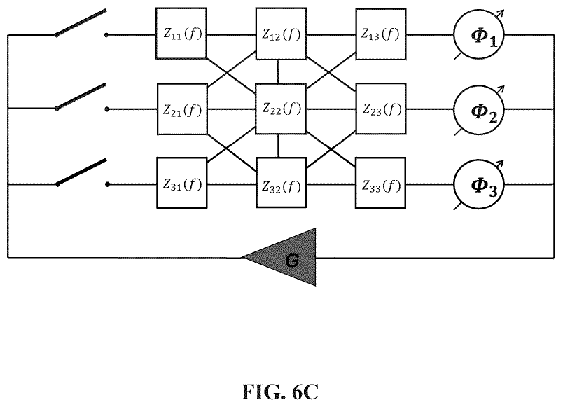

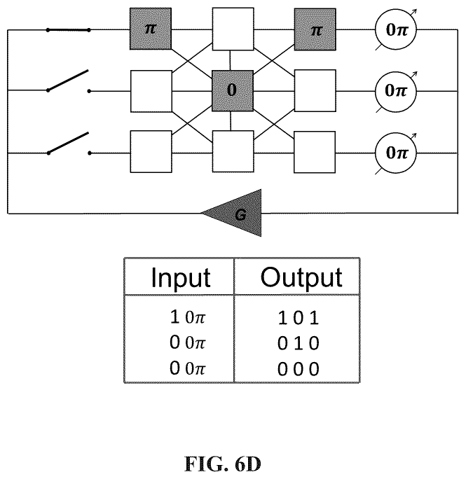

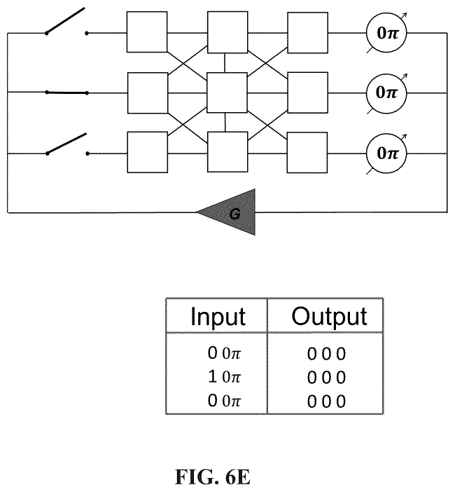

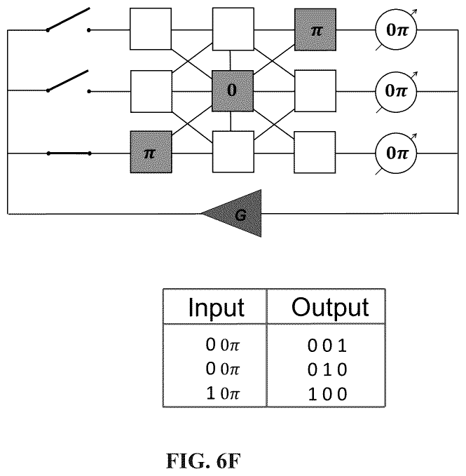

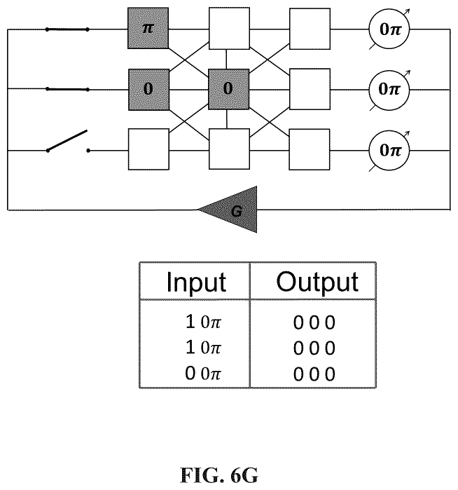

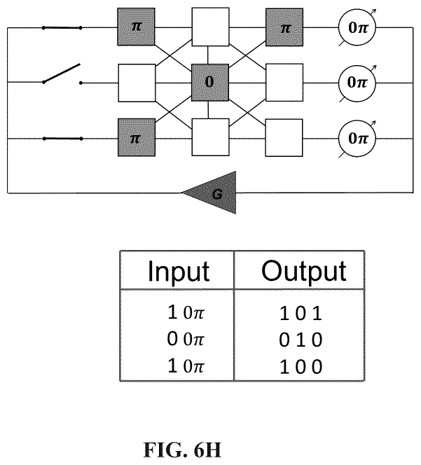

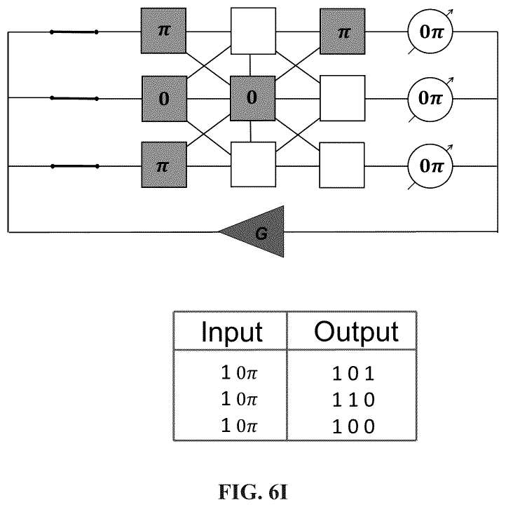

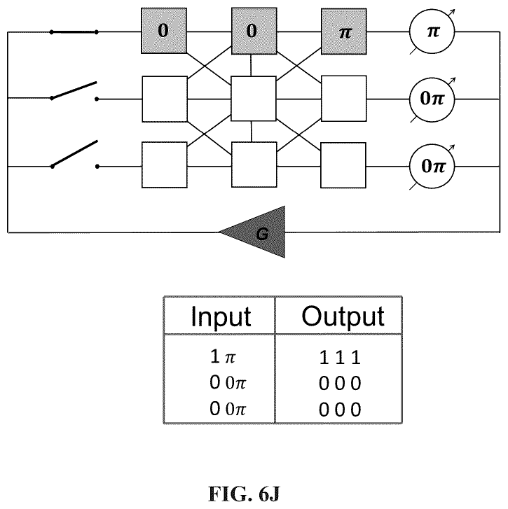

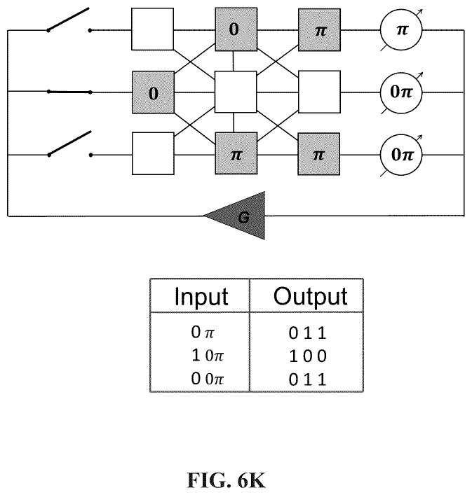

In FIG. 6A, it is shown a mesh where numbers in the boxes show the phase shift accumulated by the propagating wave. It is assumed that the output attenuators are set to exclude the paths for more than six junctions (i.e., the amplitude condition is satisfied for all paths coming through five or six junctions). The output phase shifters are set to Ψ=0.5π. The phase condition is satisfied for the paths providing 1.5π phase shift. The particular frequency(s) coming through these paths are of no importance. All the input and output switches are in the On state. The set of power detectors in FIG. 6A shows the signal propagation path for the given configuration of magnets. There are two paths. One path is from the input port #2 to the output port #1. The other path is from input port #5 to the output port #4. Let us change the places of two cells in the mesh. For example, we flip the two adjacent cells in the second row at columns two and three. It results in the change of the signal propagation path.

In FIG. 6B, the dark circles of power detectors show the paths. It can be seen that this arrangement is different from the one in FIG. 6A. The difference in the memory state is eight bits. It is possible to engineer magnonic meshes where the change in the position of just one magnet will lead to a multi-bit difference in the output. It should be noted that changing the mutual position of cells may or may not change the propagation routes in the mesh.

### 4. Illustrative Example Embodiments

FIGS. 6C to 6K disclose an illustrative example of operation of a 3×3 (9 memory cell) configuration (FIG. 6C). As disclosed in the present document, the memory address is a multi-digit binary number that is related to the states of the switches and the position of the phase shifter, and the memory state is a multi-digit binary number corresponding to the signal propagation path.

FIG. 6D shows a snapshot of the structure with resonant conditions satisfied for some frequency f₁. The waves with this frequency can propagate through the cells marked with darker color. The input-output relationships are shown in the table.

FIG. 6E shows a snapshot of the structure when there is no frequency that satisfies the resonant condition. The input-output relationship is show in the table.

FIG. 6F shows a snapshot of the structure with resonant conditions satisfied for some frequency f₁. The waves with this frequency can propagate through the cells marked with darker color. The input-output relationships are shown in the table.

FIG. 6G shows a snapshot of the structure when there is no frequency that satisfies the resonant condition. The input-output relationship is show in the table.

FIG. 6H shows a snapshot of the structure with resonant conditions satisfied for some frequency f₁. The waves with this frequency can propagate through the cells marked with darker color. The input-output relationships are shown in the table.

FIG. 6I shows a snapshot of the structure with resonant conditions satisfied for some frequency f₁. The waves with this frequency can propagate through the cells marked with darker color. The input-output relationships are shown in the table.

FIG. 6J shows a snapshot of the structure with resonant conditions satisfied for some frequency f₂ (different from the previous figures). The waves with this frequency can propagate through the cells marked with darker color. The input-output relationships are shown in the table.

FIG. 6K shows a snapshot of the structure with resonant conditions satisfied for some frequency f₂ (different from FIGS. 6C to 6I). The waves with this frequency can propagate through the cells marked with darker color. The input-output relationships are shown in the table.

### 5. Experimental Data

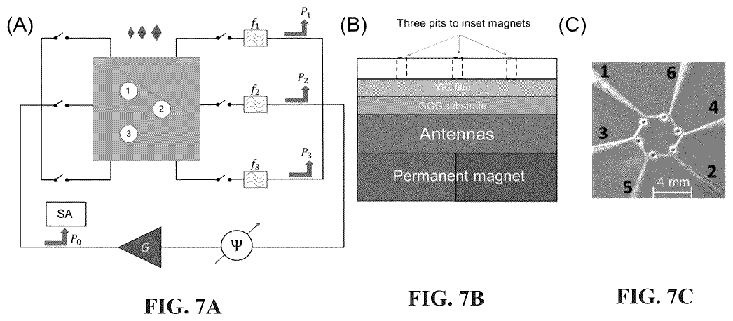

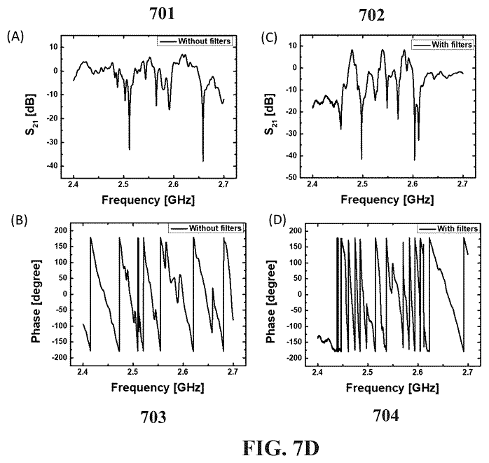

In this section, we present experimental data obtained for the prototype with just three magnets. The schematics of the prototype are shown in FIG. 7A. It is a multi-path active ring circuit comprising electric and magnetic parts. The electric part consists of an amplifier (three amplifiers Mini-Circuits, model ZX60-83LN-S+ connected in series), and a phase shifter (ARRA, model 9418A). The magnonic part is a ferrite film with three fixed places (i.e., depicted by the circles numbered 1, 2, and 3) for three different magnets to be placed on top of the film. There are three input and three output antennas to connect electric and magnetic parts. Each input/output port can be independently connected/disconnected. There are three voltage-tunable bandpass filters at the output ports. The filters are commercially available YIG-based frequency filters produced by Micro Lambda Wireless, Inc, model MLFD-40540. The experimental data on the filter transmission and phase delay can be found in the supplementary materials. The filters at output ports #1, #2, and #3 are set to the central frequencies f₁=2.539 GHz, f₂=2.475 GHz, and f₃=2.590 GHz, respectively. Magnonic and electric parts are connected via the set of splitters and combiners (i.e., SPLT 1-3, Sigatek SP11R2F 1527). The power at each output port and the total power circulating in the ring circuit is measured by the spectrum analyzer (SA) GW Instek GSP-827 connected to the circuit through a directional coupler (DC, KRYTAR, model 1850). There are four places of connection shown in FIG. 7A. P₀ is the total power in the circuit measured just after the amplifier, P₁, P₂, and P₃ are the powers measured at the output ports after signal propagation through the passive magnonic part. The signal is significantly damped after the passive part so the sum of P₁, P₂, and P₃ is not equal to P₀. SA is also used for detecting the frequencies of the auto-oscillations in the ring circuit. A more detailed schematics of the experimental setup with a detailed map of signal attenuation through the parts can be found in the Supplementary materials.

The cross-section of the passive magnonic part is shown in FIG. 7B. It consists from the bottom to the top of a permanent magnet made of NdFeB, a Printed Circuit Board (PCB) substrate with six short-circuited antennas, a ferrite film made of GGG substrate and YIG layer, and a plastic plate with three pits for magnets to be inserted. The permanent magnet is aimed to create a constant bias magnetic field. Hereafter, we refer to this relatively big permanent magnet (model BX8X84 by K&J Magnets, Inc., dimensions 1.5″×1.5″×0.25″) as a magnet in the text. The magnetic field produced by this magnet defines the frequency window as well as the type of spin waves that can propagate in the ferrite film. The bias field is about 375 Oe and is directed in-plane on the film surface. The photo of the PCB with six antennas is shown in FIG. 7C. The antennas are marked as 1, 2, 3, . . . 6. The characteristic size of the antenna is 2 mm in length and 0.15 mm in width. The ferrite film is made of YIG grown by liquid epitaxy on a GGG substrate. YIG was chosen due to the low spin wave damping. The film is not patterned. The thickness of the film is 42 μm. The saturation magnetization is close to 1750 G, the dissipation parameter (i.e., the half-width of the ferromagnetic resonance) ΔH=0.6 Oe. The plastic plate is mechanically attached on top of the ferrite film. There are three pits drilled in the layer for placing the micro-magnets. There are three NdFeB micro-magnets of volumes 0.02 mm³, 0.03 mm³, and 0.06 mm³, respectively. The magnets are placed inside plastic tubes of different colors. The smallest-volume magnet is placed into the tube of black color without a sticker. The tubes with the white and the red stickers correspond to the middle-volume and large-volume magnets respectively. Hereafter, we refer to the micromagnets as Black (B), White (W), and Red (R). The photo of the devices with tubes can be found in the Supplementary Materials.

The first set of experiments was accomplished for the case with three input and three output antennas connected. Antennas marked #3, #4, and #6 are used for spin wave excitation in the ferrite film. Antennas marked #1, #2, and #5 are used for detecting the inductive voltage produced by the spin waves at the output. The summary of experimental data is shown in Table II. The first column shows the combination of input and output switches. For instance, (111) means that all three input antennas are connected to the electric part. The second column shows the position of the external phase shifter. The external phase is set to Ψ=0π. The third column shows the magnet arrangement. For example, BWR means that B magnet (smallest) is inserted into pit #1, W magnet (medium) is inserted into pit #2, and R magnet (largest) is inserted into pit #3. Combination (000) stands for the case without magnets placed in the pits. The fourth column shows the frequencies of the auto-oscillations (i.e., measured by SA). It may be one or several frequencies at the same time. The fifth column shows the power of the auto-oscillation P₀ at different frequencies. For example, the numbers in the second row (+2 dBm and +4 dBm) correspond to the frequencies 2.590 GHz, and 2538 GHz, respectively. The sixth column shows the power measured at the three output ports, where three numbers in each row correspond to P₁, P₂, and P₃, respectively. The output power ranges from −30 dBm to −79 dBm. The last column in the table shows the logic output. It is logic 1 if the output power exceeds −45 dBm and logic 0, otherwise. Power below the reference value is shown in blue color, while the power larger than the reference power is shown in red color. For example, −27 dBm, −75 dBm, −73 dBm in the first row correspond to the memory state 100. The data presented in Table II provides a detailed picture of the active ring dynamics including the frequencies of auto-oscillation, the distribution of power between the frequencies, and the analog output at each port. There is no need in using SA in a practical device. All the collected data is aimed to explain the physical origin of data storage in MCM. The memory device will only provide binary output for the given binary address.

FIG. 7D shows four graphs presenting some of the experimental results showing spin wave transmission through the film. The bias magnetic field is about 375 Oe and directed in-plane on the film surface. Plots 701 and 702 show S21 and phase shift as a function of frequency for the film without frequency filters. Plots (703 and 704 show S21 and phase shift as a function of frequency for the film frequency filters.

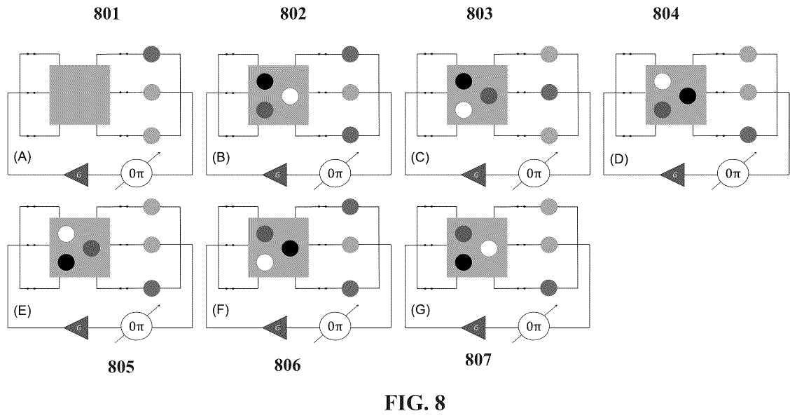

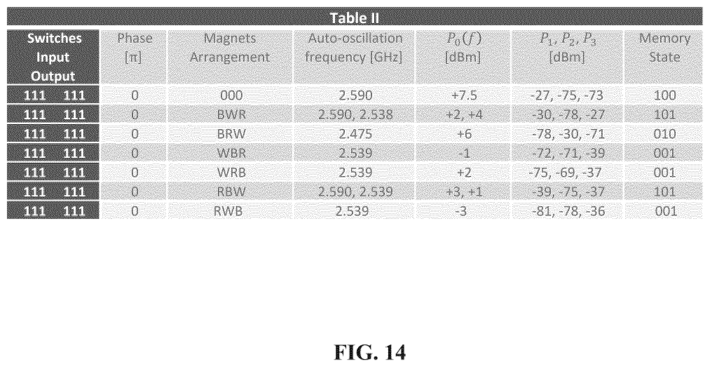

In order to visualize the data collected in Table II (refer to FIG. 14), we show the schematics of the circuit with magnet configuration and the output power distribution in FIG. 8, reference numerals 801, 802.

Table II shows raw experimental data obtained for different magnet configurations. The first column shows the combination of input and output switches. The second column shows the position of the external phase shifter. The third column shows the magnet arrangement. For example, BWR means that B magnet (smallest) is inserted into pit #1, the W magnet (medium) is inserted in pit #2, and the R magnet (largest) is inserted into pit #3. Combination (000) stands for the case without magnets placed in the pits. The fourth column shows the frequencies of the auto-oscillations (i.e., measured by SA). It may be one or several frequencies at the same time. The fifth column shows the power of the auto-oscillation P₀ at different frequencies. For example, the numbers in the second row (+2 dBm and +4 dBm) correspond to the frequencies 2.590 GHz, and 2538 GHz, respectively. The sixth column shows the power measured at the three output ports, where three numbers in each row correspond to P₁, P₂, and P₃, respectively. The last column in the table shows the logic output. It is logic 1 if the output power exceeds −45 dBm and logic 0, otherwise.

In FIG. 8, the dark circle on connector depicts the output power exceeding −45 dBm, while the grey (light) circle depicts the output power less than −45 dBm. The schematics in FIG. 8 (801) correspond to the case without magnets inserted. 802 to 807 show all possible configuration of the magnets. One can see the difference in the output power for different magnet arrangements. The experiments were carried out for different positions of the phase shifter.

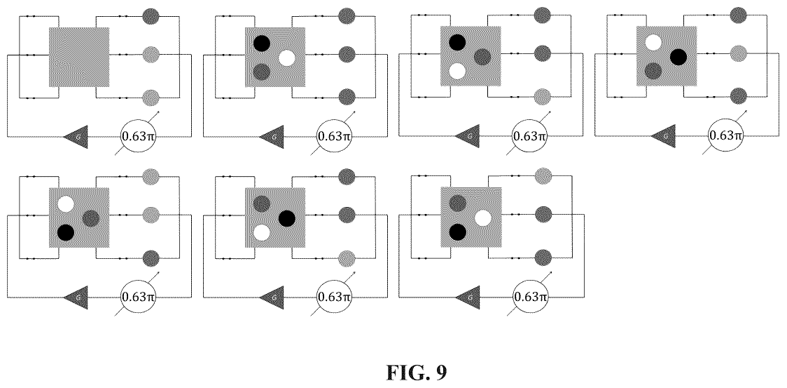

The results obtained for Ψ=0.63 π. are shown in FIG. 9. The change of state of the external voltage-tunable phase shifter results in the spin wave re-routing in the ferrite film. The experiments were repeated for the different positions of the phase shifter. Raw data can be found in the Supplementary Materials. Experimental data on spin wave paths in the system with two input and three output antennas are also included in the Supplementary Materials.

### 6. Discussion

There are two important observations we want to make based on the obtained experimental data.

(i) Spin wave propagation path(s) does depend on the configuration of magnets on top of the ferrite waveguide, the combination of input and output ports, and the output phase shifter. For instance, the arrangement of three different magnets or the arrangement of two different magnets with one empty pit results in the different spin wave propagation paths. The reason for spin wave re-routing is the difference in the magnetic field profile on the top of the ferrite film that appears for the different arrangements of magnets. The re-routing can be modeled considering magnet/ferrite film as a bandpass filter and a phase shifter as illustrated in Section 3. However, high-fidelity numerical modeling would require an enormous deal of work to link the magnetic film properties to spin wave propagation paths in a wide frequency range. The external phase is an additional parameter which affects spin wave propagation in the active ring circuit. It makes a fundamental difference with conventional RAM where low/high electric current is directly related to the high/low resistance states of the memory cells. In turn, the phase-dependent transport allows us to exploit the different combinations of input/output ports. Also, the addition of extra ports is not equivalent to the simple sum of paths and does not necessarily result in the additional paths. It may happen that some frequencies (paths) disappear for a larger number of inputs due to the spin wave interference.

(ii) Spin wave propagation paths can be recognized by the set of power sensors with high accuracy. In the presented experiments, spin wave power was measured only at the output ports (i.e., no sensors within the mesh). The On/Off ratio (i.e., the difference between the outputs where most of the power flows and the outputs with minimum power) exceeds 35 dB at room temperature. It makes it possible to tolerate the inevitable structure imperfections, the difference in the efficiency of input/output antennas, etc. This big ratio is achieved by the introduction of frequency filters aimed to separate frequency responses between the different outputs. It may be possible to achieve an even bigger On/Off ratio by using filters with a smaller bandwidth. It will take an additional comparator-based circuit to digitize MCM output.

These observations confirm the main idea of this work on the feasibility of data storage using the mutual arrangement of magnets. It inherent the advantages of traditional magnetic-based memory including non-volatility and a long retention time. At the same time, MCM provides a fundamental advantage in data storage density compared to the existing memory devices. To comprehend this advantage, we summarized the data obtained for the same set of external phase shifters but with the different configurations of magnets.

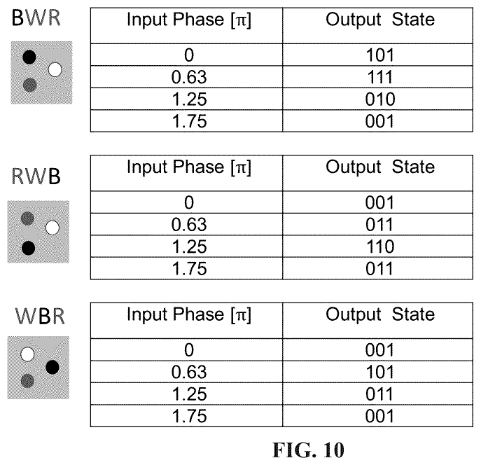

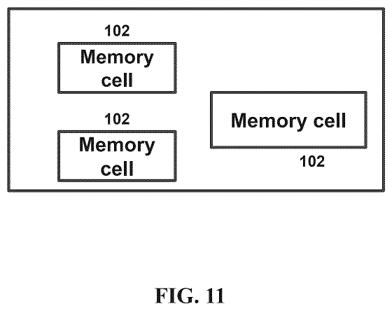

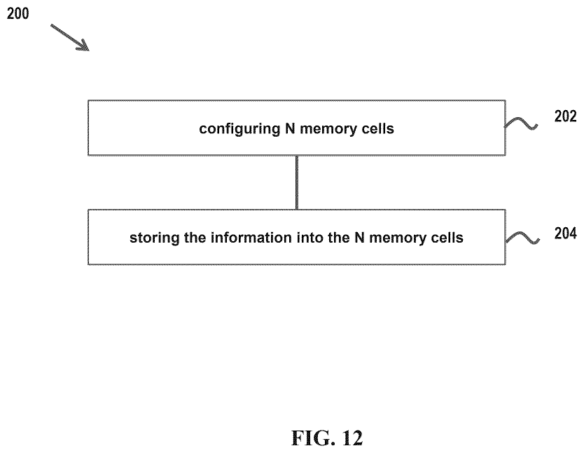

FIG. 10 shows examples of arrangement of magnets on the left and the corresponding truth tables for four phases on the right. There are three bits corresponding to the memory state in each row. Conventional memory with three magnets stores just three bits. It is the same amount of data that can be read-out at one given phase in MCM (e.g., phase=0 π). All other rows (i.e., 3 out of 4 in each table) contain extra or exceed information compared to conventional RAMs. According to Eq.(8), the advantage over the conventional data storage devices scales as the power law of the size of magnonic mesh n×n.

The following comments may be observed:

(i) The structure of the prototype is different from the general view MCM shown in FIG. 4. There are only three output ports in the prototype. The addition of power sensors within the magnetic part (e.g., between the magnets) would give a better picture of the spin wave path. The ISHE sensors may need frequency filters for spin wave path detection.

(ii) Some embodiments may use different magnets (i.e., magnets providing different phase shift/amplitude changes to the propagating spin waves), which should be taken into account by fabrication and initialization procedure. For instance, one has to have 25 different magnets to differentiate all possible paths in the device shown in FIG. 4. There are no practical challenges associated with the fabrication of 25 magnets of different sizes or shapes on top of ferrite film. However, the change of the magnetization state after the fabrication becomes a very challenging problem. Theoretically, the post-fabrication initialization can be achieved using spin waves and specially engineered magnetic bits. In our preceding work, it was considered micro-structured magnetic bits for better interaction with spin waves. The switching was observed in ferromagnet/ferrimagnet hybrid structures consisting of Ni₈₁Fe₁₉ nanostripes prepared on top of YIG film. Alternatively, magnetization switching can be accomplished by all-optical tools without a magnetic field. It may be a convenient way for MCM programming. Thus, the design and control of magnets in magnonic mesh is based on a careful fabrication and initialization process.

During our experimentation, we observed that it takes less than one millisecond for the prototype circuit to reach saturation. The estimated power consumption is about 1 μJ per 3-bit retrieval. The size of the magnetic part of the prototype is about 10 mm×10 mm.

However, embodiments can be designed to reduce the time factor. The time required for auto-oscillation to come to the steady-state regime depends on the parameters of the magnetic mesh and the characteristics of the amplifier. The group velocity of magnetostatic spin waves is about 10′ m/s. The read-out time can be minimized by the scaling down of magnonic mesh size. There are no physical constraints for scaling down the size of the magnets to the tens of nanometers. It may be possible to place a 1000×1000 micro-magnet array on the 10 mm×10 mm ferrite film. The scaling down can also minimize spin wave losses and reduce power consumption. MCM may not be capable of competing with conventional memory in the time of single-bit addressing or energy required for single-bit read-out. However, MCM enables a multi-bit read-out. The number of bits read-out at a time by MCM scales proportional to the size of the mesh n×n. It makes MCM efficient for a large mesh with a large number of cells.

The utilization of phase in addition to amplitude is the reason for data storage density enhancement in MCM. It opens a new dimension for information encoding. In this work, we considered an approach where multiple paths on the grid are differentiated by the accumulated phase shift. It is possible to have a unique phase shift for each of the possible paths (i.e., the phase shift of a cell is proportional to a prime number). In turn, it increases the number of memory addresses one can use. Conventional memory devices (e.g., RAM) use only of a portion of possible cell addresses (i.e., one column/one row). MCM can utilize all possible combinations of input/output switches (e.g., the inputs/three outputs, four inputs, two outputs, etc.). The ability to control the phase shifters at each output port gives an additional degree of freedom. Overall, MCM provides a fundamental advantage in the data storage density compared to conventional memory devices.

It may be possible to utilize MCM as a RAM for some specific applications that deal with large sets of data (e.g., image processing). It may take less time to re-arrange n magnets than to change one-by-one the states of n! memory cells in conventional memory. It is important to develop a mechanism for fast and low-power consuming magnetization switching (e.g., all-optical magnetic switching) to make MCM attractive for RAM applications.

### 7. Concluding Remarks

It will be appreciated by those of skill in the art that the present document discloses a novel type of magnetic memory that is aimed to exploit the mutual arrangement of magnets for data storage. The principle of operation is based on the correlation between the arrangement of magnets on top of ferrite film and the spin wave propagation paths. The number of paths scales factorial with the number of magnets that makes it possible to encode more information compared to conventional magnetic memory devices exploiting the individual states of magnets. We presented experimental data on the proof-of-the-concept experiments on the prototype with just three magnets placed on top of a of single-crystal yttrium iron garnet Y₃Fe₂(FeO₄)₃ (YIG) film. The results demonstrate a robust operation with an On/Off ratio for path detection exceeding 35 dB at room temperature. This work is a first step toward the novel type of combinatorial memory devices which have not been explored. The material structure and principle of operation of MCM are much more complicated compared to conventional RAMs. At the same time, MCM may pave the road to unprecedented data storage capacity where a device with an array of 100×100 magnets can store all information generated by humankind.

### 8. Additional Examples

### 8.1 Device Fabrication

The core of the device may be made of single crystal Y₃Fe₂(FeO₄)₃ film. The film was grown on top of a (111) Gadolinium Gallium Garnett (Gd₃Ga₅O₁₂) substrate using the liquid-phase epitaxy technique. The thickness of the film is 42 μm. The saturation magnetization is close to 1750 G, the dissipation parameter (i.e., the half-width of the ferromagnetic resonance) ΔH=0.6 Oe. The bias magnetic field is provided by the permanent magnet made of NdFeB.

### 8.2 Further Embodiments

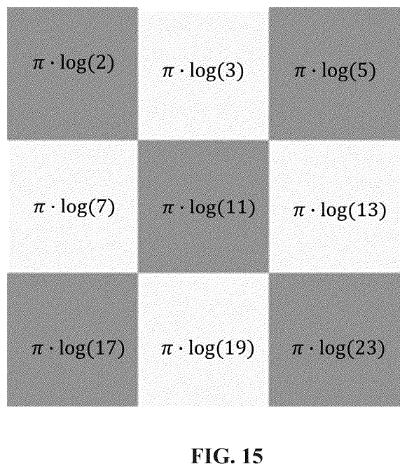

FIG. 15 shows an example configuration of memory cells which illustrates the possibility that it is possible to build a mesh where each cell provides a phase shift proportional to the logarithm of a prime number. Due to this, all paths will have unique phase shifts.

### 9. Example Technical Solutions

Some example technical solutions implemented by preferred embodiments include:

1. A data storage apparatus (e.g., apparatus 100 depicted in FIG. 1), comprising: N memory cells (102), where N is an integer greater than 1; wherein each memory cell is controllable to conform to a plurality of arrangements, and wherein the data storage apparatus is configured to store data using a collective arrangement of the N memory cells. For example the plurality of arrangements may be plurality of path arrangements and the data is stored using the collective arrangement of paths among the N memory cells.

2. The data storage apparatus of solution 1, wherein each memory cell is a magnetic memory cell.

3. The data storage apparatus of solution 1, wherein each memory cell is an electrical memory cell. Although magnonic cells are used to illustrate the path uniqueness, it is possible to construct the memory cell array using optical or mechanical memory cell that also exhibit similar frequency and phase properties as disclosed herein.

4. The data storage apparatus of above solutions, wherein the data storage apparatus is configured to store (N²)! distinct information values (see Equation 5).

5. The data storage apparatus of above solutions, wherein the data storage apparatus is configured to store N! distinct information values.

6. The data storage apparatus of above solutions wherein the data is encoded into spin wave propagation routes.

In some embodiments, the N memory cells are organized as a two-dimensional (2D) grid comprising a first number N1 of rows and a second number N2 of columns. Thus, N=N1×N2. The data storage apparatus further includes N1 left switches and N1 right switches coupled to the N memory cells a tunable amplifier and a tunable phase shifter coupled in series to the N1 left switches and the N1 right switches. For example, in various figures, examples of 4×4 (FIGS. 3A-3D), 5×5 (FIG. 5, 6A, 6B) and 3×3 (FIGS. 6C to 6K) are shown. In general, N1 and N2 do not have to be same numbers. Here, N1 and N2 are positive integers, preferably greater than 1.

In some embodiments, wherein the tunable phase shifter has a frequency dependent operational characteristic. In some embodiments, the apparatus further includes an electrically controllable phase shifter coupled in series to the N1 left switches and the N1 right switches. In some embodiments, the following conditions are satisfied:

$$G ( V ) + L ( f ) \geq 1 ,$$

$$Ψ ( V ) + Δ ( f ) = 2 π k , where k = 1 , 2 , 3 , … ( positive integers )$$

where G(V) is gain provided by the tunable amplifier, L(f) is a signal attenuation in the 2D grid, Δ(f) is a phase shift of the 2D grid, and Ψ(V) is a phase shift of the electrically controllable phase shifter and f represents frequency. In some embodiments, the apparatus may include a controller (e.g., one or more processors) that is configured to access the N memory cells for reading or writing data based on an on/off combination of the N1 left switches and the N1 right switches. In some embodiments, each memory cell comprises Y₃Fe₂(FeO₄)₃ material.

7. A method of storing information (e.g, method 200 depicted in FIG. 2), comprising: configuring (202) N memory cells, where N is an integer greater than 1; wherein each memory cell is controllable to conform to a plurality of arrangements, and wherein the data storage apparatus is configured to store data using a collective arrangement of the N memory cells; and storing (204) the information into the N memory cells. In some embodiments, the plurality of arrangements refer to path arrangements among the N memory cells, and preferably among cells on opposite edges of a matrix formed by the arrangement of the memory cells in a 2D manner. Here, the configuration of memory cells may be achieved by applying the ring circuit as disclosed herein.

8. The method of solution 7, wherein each memory cell is a magnetic memory cell.

9. The method of solution 7, wherein each memory cell is an electrical memory cell.

10. The method of above solutions, wherein the data storage apparatus is configured to store (N²)! distinct information values.

11. The method of above solutions, wherein the data storage apparatus is configured to store N! distinct information values.

12. The method of above solutions wherein the data is encoded into spin wave propagation routes. The above method may further include reading from the memory storage device/apparatus, writing, rewriting to the apparatus, and so on.

The method may further include features as described with respect to the apparatus solutions described herein.

13. A method of fabricating a memory storage apparatus.

14. A method, an apparatus or a system as disclosed herein.

United States Patent Publication US20230410927A1, incorporated by reference herein in its entirety discloses some embodiments of a ring memory that may be used as a starting point for implementing some embodiments disclosed in the present document.

It will be appreciated that the present document discloses a new type of data storage mechanism in which memory cells are organized as a two dimensional array, with two opposite sides designated as the input and output sides and data being stored using pathways connecting between memory cells on the opposite sides. In particular, for a magnonic memory, the combination of phase and frequency selectivity may be used to write data to, or read data from, the 2D memory cell matrix, where the data is stored using path combinatorics.

It should be noted that the methods described above describe possible implementations, and that the operations and the steps may be rearranged or otherwise modified and that other implementations are possible. Furthermore, embodiments from two or more of the methods may be combined.

The disclosed and other embodiments, modules and the functional operations described in this document can be implemented in digital electronic circuitry, or in computer software, firmware, or hardware, including the structures disclosed in this document and their structural equivalents, or in combinations of one or more of them. The disclosed and other embodiments can be implemented as one or more computer program products, i.e., one or more modules of computer program instructions encoded on a computer readable medium for execution by, or to control the operation of, a data processing apparatus. The computer readable medium can be a machine-readable storage device, a machine-readable storage substrate, a memory device, a composition of matter effecting a machine-readable propagated signal, or a combination of one or more them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. A propagated signal is an artificially generated signal, e.g., a machine-generated electrical, optical, or electromagnetic signal, that is generated to encode information for transmission to suitable receiver apparatus.

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this document can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

While this patent document contains many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. A data storage apparatus, comprising:
N memory cells, where N is an integer greater than 1;
wherein each memory cell is controllable to conform to a plurality of path arrangements among the N memory cells, and
wherein the data storage apparatus is configured to store data using a collective arrangement of paths among the N memory cells.

2. The data storage apparatus of claim 1, wherein each memory cell is a magnetic memory cell.

3. The data storage apparatus of claim 1, wherein each memory cell is an electrical memory cell, an optical memory cell or a mechanical memory cell.

4. The data storage apparatus of claim 1, wherein the data storage apparatus is configured to store or N! distinct information values.

5. The data storage apparatus of claim 1, wherein each path of the plurality of path arrangements is associated with a binary number that corresponds to an information value in the data stored in the data storage apparatus.

6. The data storage apparatus of claim 1, wherein the data is encoded into spin wave propagation paths among memory cells.

7. The data storage apparatus of claim 1, wherein the N memory cells are organized as a two-dimensional (2D) grid comprising a first number N1 of rows and a second number N2 of columns, the data storage apparatus further including:
N1 left switches and N1 right switches coupled to the N memory cells,
a tunable amplifier and a tunable phase shifter coupled in series to the N1 left switches and the N1 right switches.

8. The data storage apparatus of claim 7, wherein the tunable phase shifter has a frequency dependent operational characteristic.

9. The data storage apparatus of claim 8, further including an electrically controllable phase shifter coupled in series to the N1 left switches and the N1 right switches.

10. The data storage apparatus of claim 9, wherein the data storage apparatus satisfies following conditions:
$$G ( V ) + L ( f ) \geq 1 ,$$
$$Ψ ( V ) + Δ ( f ) = 2 π k , where k = 1 , 2 , 3 , …$$
where G(V) is gain provided by the tunable amplifier, L(f) is a signal attenuation in the 2D grid, Δ(f) is a phase shift of the 2D grid, and Ψ(V) is a phase shift of the electrically controllable phase shifter and f represents frequency.

11. The data storage apparatus of claim 7, including a controller that is configured to access the N memory cells for reading or writing data based on an on/off combination of the N1 left switches and the N1 right switches.

12. The data storage apparatus of claim 1, wherein each memory cell comprises Y₃Fe₂(FeO₄)₃ material.

13. A method of operating a data storage apparatus, comprising:
configuring N memory cells, where N is an integer greater than 1;
wherein each memory cell is controllable to conform to a plurality of path arrangements among the N memory cells, and
wherein the data storage apparatus is configured to store data using a collective arrangement of paths among the N memory cells; and
storing data into the N memory cells using a collective arrangement of paths among the N memory cells.

14. The method of claim 13, wherein each memory cell is a magnetic memory cell.

15. The method of claim 13, wherein each memory cell is an electrical memory cell.

16. The method of claim 13, wherein the data storage apparatus is configured to store N! distinct information values.

17. The method of claim 13, wherein the N memory cells are organized as a two-dimensional (2D) grid comprising a first number N1 of rows and a second number N2 of columns, the method further including:
controlling N1 left switches and N1 right switches coupled to the N memory cells to read from or write to the 2D grid; and
controlling a tunable amplifier and a tunable phase shifter coupled in series to the N1 left switches and the N1 right switches such that a spin wave signal propagates through the 2D grid.

18. The method of claim 17, wherein, for each information value, the reading from or writing to the 2D grid uses a unique on/off combination of the N1 left switches and the N1 right switches.

19. The method of claim 17, wherein the method is implemented according to following conditions:
$$G ( V ) + L ( f ) \geq 1 ,$$
$$Ψ ( V ) + Δ ( f ) = 2 π k , where k = 1 , 2 , 3 , …$$
where G(V) is gain provided by the tunable amplifier, L(f) is a signal attenuation in the 2D grid, Δ(f) is a phase shift of the 2D grid, and Ψ(V) is a phase shift of an electrically controllable phase shifter and f represents frequency.

20. The method of claim 13, wherein the configuring the N memory cells includes:
initializing the N memory cells to a saturated state of operation.
